(19) United States
(12) Patent Application Publication
(10) Pub. No.: US 2025/0248148 A1
(43) Pub. Date: Jul. 31, 2025

(54) LOW COST MASK REDUCTION FOR HIGHLY RELIABLE IGZO TFT BACKPLANES

(71) Applicant: dpiX, LLC, Colorado Springs, CO (US)

(72) Inventors: Jerome David Crocco, Colorado Springs, CO (US); Jinhui Cho, Colorado Springs, CO (US); Geun Jo Han, Colorado Springs, CO (US)

(21) Appl. No.: 19/022,196

(22) Filed: Jan. 15, 2025

Related U.S. Application Data
(60) Provisional application No. 63/626,219, filed on Jan. 29, 2024.

(51) Int. Cl. H10F 39/00; H10D 30/01; H10D 30/67; H10F 30/223; H10F 71/00

(52) U.S. Cl. CPC H10F 39/80377; H10D 30/031; H10D 30/6756; H10F 30/2235; H10F 71/121

(57) ABSTRACT

A semiconductor device includes an active matrix, using Indium Gallium Zinc Oxide (IGZO) as a semiconductor layer, wherein the IGZO is patterned to create distinct conductive and semiconductive regions across the active matrix, and wherein the semiconductor device comprises an IGZO TFT.

### CROSS-REFERENCE TO RELATED APPLICATIONS

This application claims the benefit of U.S. Provisional Application No. 63/626,219, filed on Jan. 29, 2024, which application is hereby incorporated herein by reference.

### TECHNICAL FIELD

The present invention relates generally to low cost mask reduction for highly reliable Indium Gallium Zinc Oxide (IGZO) thin film transistor (TFT) backplanes, and a corresponding manufacturing method.

### BACKGROUND

Traditionally, IGZO TFTs have been integrated with amorphous Silicon (a-Si) and Low-Temperature Polycrystalline Silicon (LTPS) processes to create active matrix backplanes for displays and image sensors. However, challenges such as hydrogen-induced conductivity, thermal budget management, and cost-effective integration have limited the performance and economic viability of these technologies. Existing approaches often involve complex multi-layer structures that require a high number of patterning masks, leading to increased production costs. Furthermore, the sensitivity of IGZO to hydrogen diffusion during a-Si deposition has posed significant reliability issues, impacting the long-term performance of devices. The related art reveals a need for an IGZO active matrix architecture that addresses these concerns and is conducive to integration into existing semiconductor process flows.

### SUMMARY

According to an embodiment, a semiconductor device comprises an active matrix, using Indium Gallium Zinc Oxide (IGZO) as a semiconductor layer, wherein the IGZO is patterned to create distinct conductive and semiconductive regions across the active matrix, and wherein the semiconductor device comprises an IGZO TFT.

According to an embodiment, a method for manufacturing a semiconductor device, wherein the semiconductor device comprises an IGZO TFT, comprises depositing and patterning an IGZO layer on a SiO₂ buffer layer to create an active matrix with differentiated conductive and semiconductive regions.

According to an embodiment, a method of manufacturing an image sensor comprises forming a patterned Indium Gallium Zinc Oxide (IGZO) layer on a buffer layer over a substrate; forming a gate dielectric layer over the patterned IGZO layer; forming a sensor over a portion of the gate dielectric layer; encapsulating the sensor with an interlayer dielectric layer; forming vias in the interlayer dielectric layer; and metalizing the vias in the interlayer dielectric layer, wherein the gate dielectric layer and the interlayer dielectric layer are both subjected to plasma treatments to form a dual hydrogen barrier.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a combined cross-sectional view, flow chart, and plan view of a manufacturing process associated with a first mask, according to an embodiment;

FIG. 2 is a combined cross-sectional view, flow chart, and plan view of the manufacturing process associated with a second mask, according to an embodiment;

FIG. 3 is a combined cross-sectional view, flow chart, and plan view of the manufacturing process associated with a third mask, according to an embodiment;

FIG. 4 is a combined cross-sectional view, flow chart, and plan view of the manufacturing process associated with a fourth mask, according to an embodiment;

FIG. 5 is a combined cross-sectional view, flow chart, and plan view of the manufacturing process associated with a fifth mask, according to an embodiment;

FIG. 6 is a combined cross-sectional view, flow chart, and plan view of the manufacturing process associated with a sixth mask, according to an embodiment;

FIG. 7 is a cross-sectional view of a hydrogen barrier associated with the manufacturing process shown in FIG. 1 through FIG. 6, according to an embodiment;

FIG. 8 is a combined flow chart and cross-sectional view of a completed image sensor manufactured according to the above manufacturing process, according to an embodiment;

FIG. 9 is a flow chart associated with the hydrogen barrier shown in FIG. 7; and

FIG. 10 is a more detailed cross-sectional view of the hydrogen barrier shown in FIG. 7, according to an embodiment.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

According to embodiments, a semiconductor device and method for fabricating an active matrix uses Indium Gallium Zinc Oxide (IGZO) technology that is integrated with amorphous silicon (a-Si) and Low-Temperature Polycrystalline Silicon (LTPS) processes. An embodiment architecture reduces manufacturing complexities and costs while maintaining high-performance standards, specifically for applications in high-resolution medical imaging and displays.

The IGZO active matrix is constructed on a glass substrate or flexible substrate with an SiO₂ buffer layer, which serves to prevent the diffusion of impurities. The IGZO layer is deposited and patterned to form conductive source and drain regions while maintaining a semiconducting channel under the gate. According to an embodiment, a gate dielectric layer comprises SiO₂, which is subjected to N₂O plasma treatments to integrate high-density SiN barriers that effectively impede hydrogen penetration. These barriers advantageously maintain the integrity and stability of the IGZO channel.

According to an embodiment, the device also comprises a multi-layer cathode structure including a Titanium Tungsten/Aluminum/Titanium Tungsten/Chromium (TiW/Aluminum/TiW/Cr) stack and a sensor layer comprising an a-Si photodiode topped with an Indium Tin Oxide (ITO) electrode. An interlayer dielectric encapsulates the sensor and is patterned with vias for electrical connectivity, while the top metal layer, also comprising TiW/Aluminum/TiW, ensures fast signal switching and minimal noise in TFT operation. An optional passivation layer provides device protection.

According to an embodiment, the IGZO active matrix provides a cost-effective solution with enhanced performance, especially in preventing hydrogen-induced degradation, a common challenge with existing IGZO implementations. The method of fabrication includes steps that are tailored to integrate with standard a-Si and LTPS manufacturing workflows, ensuring broad applicability across various electronic domains.

According to embodiments, an IGZO active matrix architecture is further described below that is compliant with integration into a-Si and LTPS processes as well as mask count reduction leading to overall lower cost. The IGZO active matrix can be particularly used for medical imaging applications, but can also be used for IGZO TFT backplanes that require integration with LTPS in display or mobile applications.

The challenges of integrating IGZO with a-Si photodiode for imaging applications is described below:

IGZO layer: the IGZO layer can become conductive as a result of a large amount of Hydrogen used during a-Si deposition. The IGZO S/D contacts should be conductive while the IGZO beneath the gate should be semiconducting.

Thermal Budget Management: IGZO deposition typically requires a lower thermal budget compared to LTPS and a-Si processes. Balancing these different thermal requirements without compromising the structural and electronic properties of the materials is a significant challenge. The thermal stability of IGZO should be maintained during the high-temperature processing steps of a-Si or LTPS.

Cost-Effective Integration: While IGZO promises reduced mask counts and potentially lower costs, the integration process should be cost-effective without compromising performance. This involves optimizing the manufacturing process to minimize waste and increase yield.

An embodiment method comprises patterning the IGZO Source and Drain to ensure that the IGZO layer can be modulated in the x-y plane to be conductive or semiconductive depending on the requirements. That is, the source-drain areas of the IGZO layer have metal electrodes present to ensure conducting characteristics and the channel area of the IGZO will not have metal electrodes present to ensure semi-conducting characteristics.

The use of intense N₂O plasma treatments on IGZO gate dielectric form a high density of SiN barriers to Hydrogen penetration. According to embodiments, plasma powers per m² can be up to 3-10 kW and the layer densities can be as dense as every 10 A for a total thickness in the range of 1000˜4000 A.

The use of intense plasma treatments on the interlayer dielectric form a high density of multiple SiN layers to prevent Hydrogen penetration. According to embodiments, plasma powers per m² can be up to 3-10 kW and the layer densities can be as dense as every 10 A for a total thickness in the range of 1000˜4000 A.

The use of a thick (>1 μm, in an embodiment) TiW/Aluminum layer top gate ensures fast rise and fall time to minimize TFT noise.

According to embodiments, the architecture is characterized by a ‘Top Gate’ configuration which includes a sequence of layers designed to optimize the semiconductor properties of IGZO while addressing the common challenges faced in traditional processes. This includes:

A SiO₂ buffer layer deposited on glass, or on a flexible substrate, which serves to prevent the diffusion of contaminants into the IGZO channel.

An IGZO layer patterned to differentiate between conductive source/drain regions and a semiconducting channel beneath the gate.

A Chemical Vapor Deposition (CVD) dielectric layer functioning as the gate dielectric with superior hydrogen barrier properties, achieved through intensive plasma treatments.

A multi-layer cathode structure comprising a refractory metal layer (TiW) and aluminum, designed to serve as the anode for the subsequently deposited sensor layer while also contacting the drain of the IGZO TFT.

A sensor layer formed from a CVD-deposited a-Si photodiode or similar sensing structure, capped with an ITO electrode.

An interlayer dielectric encapsulation, consisting of SiON or SiO₂ or SiN, patterned with vias to connect to the a-Si photodiode cathode and the source of the IGZO TFT.

A top metal layer, using the same TiW/Aluminum/TiW stack, providing electrical connections and ensuring rapid signal readout with minimized noise.

An optional passivation layer to protect the device, with openings for external connections.

According to embodiments, a method for patterning the IGZO source and drain creates areas with distinct electrical properties, which are modulated according to device requirements. Additionally, embodiments employ plasma treatments to form high-density SiN layers as effective hydrogen barriers, with different film density and thickness with plasma power for a total thickness of up to 4000 Angstroms that has a bilayer structure. The top metal gate is notably thick (>1 μm) to facilitate fast signal switching and minimize TFT noise.

According to embodiments, the IGZO active matrix architecture thus represents a significant advancement in the field of semiconductor device fabrication, addressing existing technological gaps while providing a scalable and economically viable solution for a range of electronic applications.

The overall architecture is referred to as a “Top Gate” architecture and includes the following layers described in further detail below:

Semiconductor: SiO₂ buffer deposition on glass and Physical Vapor Deposition (PVD) IGZO blanket deposition and patterning. The IGZO layer is used as the switching semiconductor channel component of the active matrix. The buffer is used to prevent any leaching of alkaline material into the IGZO channel.

Gate Dielectric: CVD Dielectric (SiO₂) deposition onto the IGZO.

Cathode: PVD Metal Electrode (TiW/Aluminum/TiW/Cr). The Layer is used for forming the bottom cathode of the diode which is deposited next and contacting drain of the IGZO TFT (hence the use of TiW a refractory material that will not dope IGZO).

Sensor: CVD deposition of a-Si photodiode or another a-Si sensing layer is deposited. This comprises an NIP diode capped with an ITO electrode. This layer is patterned into a photodiode using a dry etch to remove the a-Si. Then the metal electrode is patterned to form the gate.

Interlayer dielectric: Dielectric encapsulation of the a-Si photodiode using a combination of SiON or SiO₂ capped with SiN. This layer is then patterned with vias to connect to the Cathode of the a-Si photodiode and the source of the IGZO TFT.

Top metal layer (TiW/Aluminum/TiW) used for connecting to the cathode of the diode as well as connecting to the drain of the TFT for reading out a low Dataline.

Passivation layer (optional) and opening for encapsulating the metal lines.

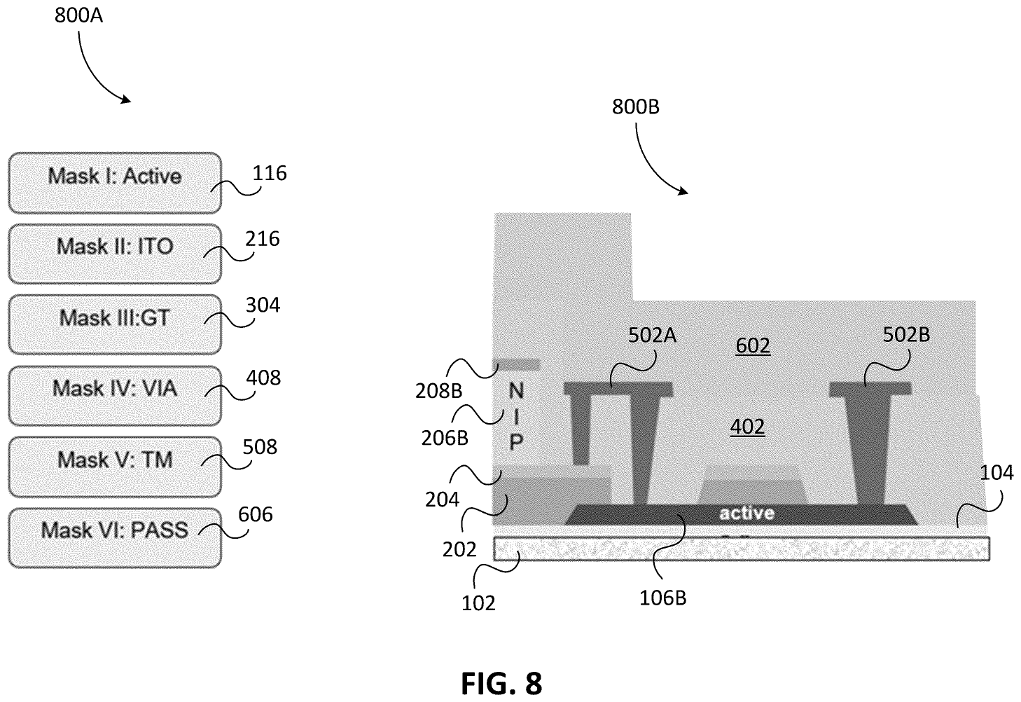

FIG. 8 is a combined flow chart and cross-sectional view of a completed image sensor manufactured according to the above manufacturing process, according to an embodiment. Flow chart 800A shows the mask layers that are sequentially used in the IGZO active matrix architecture to form an image sensor device. Flow chart 800A shows a first mask 116 (Active), a second mask 216 (ITO), a third mask 304 (GT), a fourth mask 408 (VIA), a fifth mask 508 (TM), and a sixth mask 606 (PASS), all of which are described in further detail below.

FIG. 8 also shows each of the layers that are present in the completed image sensor 800B including a substrate 102, a buffer layer 104, an active layer 106B, a gate dielectric layer 202, a cathode layer 204, a sensor layer 206B, an ITO electrode layer 208B, an interlayer dielectric 402, a top metal layer including cathode contact 502A and drain contact 502B, and a passivation layer 602.

According to an embodiment, each of the masks are used in a semiconductor manufacturing process flow for an IGZO (Indium Gallium Zinc Oxide) active matrix, potentially for use in TFT (Thin-Film Transistor) applications such as displays or sensors. The process flow comprises six steps, each associated with a mask that is used to pattern a specific layer or set of features on the device. Each step is associated with a corresponding mask:

Mask 1: Active (116). A thin SiO₂ buffer layer is deposited on a glass substrate and annealed. IGZO is then deposited and subjected to an activation anneal. The IGZO layer is etched according to the active area pattern, and a cure anneal process is applied. The Gate Dielectric layer is deposited on IGZO. A top gate metal layer is deposited on Gate Dielectric layer.

Mask 2: Sensor (216). A layer of n-i-p (which may represent a semiconductor stack of n-type, intrinsic, and p-type layers) is deposited. And ITO (Indium Tin Oxide) may be used for transparent electrodes. This is followed by sensor wet/dry etching to pattern the sensor elements.

Mask 3: Top Gate (304). The gate metal and Gate Dielectric (possibly a conductive or dielectric layer) are etched to define the top gate structures.

Mask 4: Interlayer Dielectric and Via (408). An Interlayer Dielectric (ILD) is deposited. Vias (vertical interconnect accesses) are created through the ILD by dry etching.

Mask 5: Top Metal (508). Top Metal (TM) is deposited, which will serve as the upper electrode or interconnect. The TM is etched to define the metal lines and contacts.

Mask 6: Passivation (606) A passivation layer is deposited to protect the underlying circuitry. The passivation layer is etched to open up areas for further contacts or to define the final device geometry.

Each of these steps involves a combination of deposition, patterning, and etching processes. The process flow suggests a focus on reducing mask count, which implies fewer lithography steps and potentially lower production costs. Integration of this IGZO active matrix architecture into aSi and LTPS processes would require careful consideration of the thermal budgets, chemical compatibilities, and electrical properties to ensure that the IGZO performs reliably in the final device.

This manufacturing process results in high-performance IGZO active matrices suitable for use in high-resolution medical imaging applications or in display technology for mobile devices, where the unique properties of IGZO such as high mobility and transparency are advantageous.

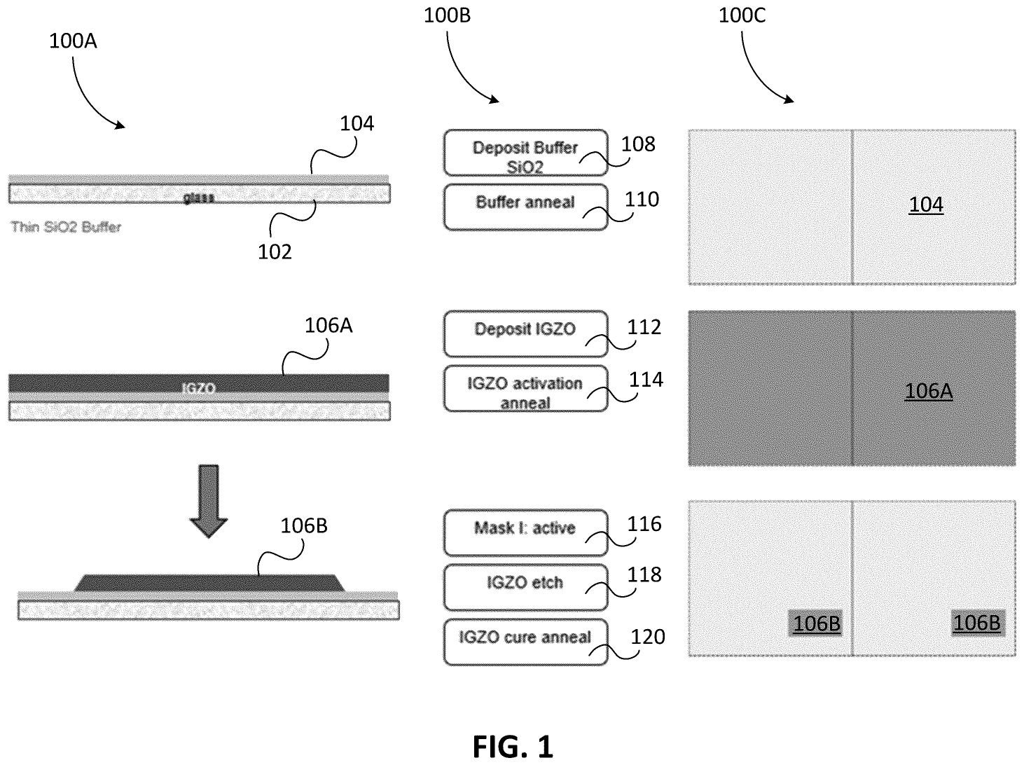

FIGS. 1-6 each show a combined cross-sectional view, flow chart, and plan view of a manufacturing process associated with a first mask, according to an embodiment;

FIG. 1 shows the cross-sectional views 100A, the flow chart steps 100B, and the plan view 100C of the manufacturing steps associated with Mask 1: Active (116).

The top cross-sectional view shows a glass substrate 102 and a buffer layer 104. The corresponding flow chart steps are depositing the buffer layer 104 on the glass substrate 102 at step 108. In an embodiment, the buffer layer 104 comprises an SiO₂ buffer layer. After the buffer layer 104 is deposited it is annealed at step 110. The corresponding plan view of the buffer layer 104 is also shown.

The center cross-sectional view shows the glass substrate 102, the buffer layer 104, and an IGZO layer 106A on top of the buffer layer 104. The corresponding flow chart steps are depositing the IGZO layer 106A on the buffer layer 104 at step 112. After the IGZO layer 106A is deposited it undergoes an activation anneal at step 114. The corresponding plan view of the IGZO layer 106A is also shown.

The bottom cross-sectional view shows the IGZO layer 106A etched and patterned into an active layer 106B. The corresponding flow chart steps are using the first mask 116 (Active), etching the IGZO layer at step 118, and performing a cure anneal at step 120. The corresponding plan view of the buffer layer 104 and the active layer 106B is also shown.

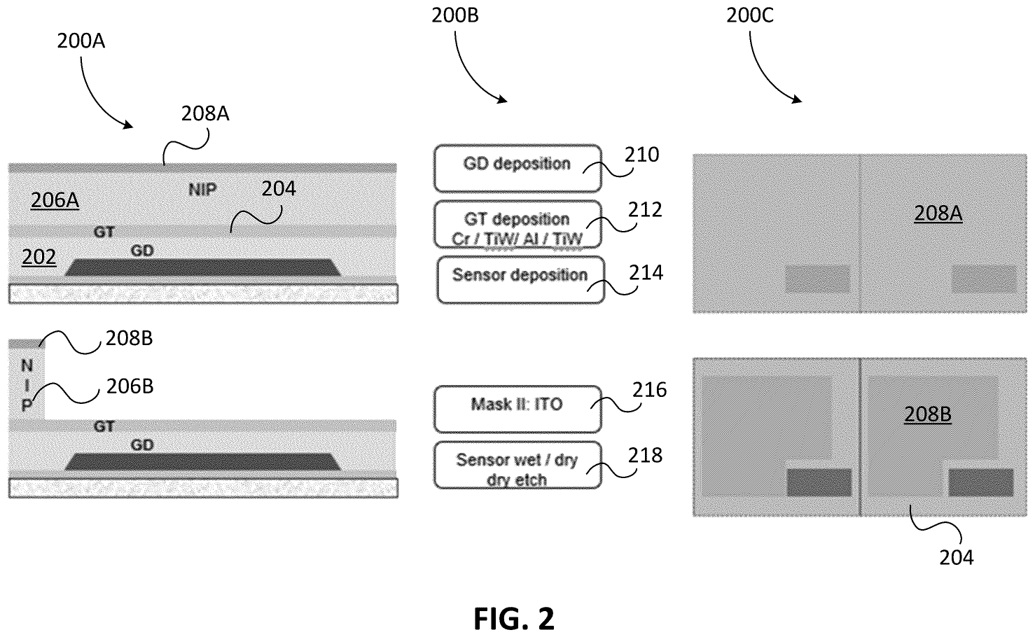

FIG. 2 shows the cross-sectional views 200A, the flow chart steps 200B, and the plan view 200C of the manufacturing steps associated with Mask 2: ITO (216).

The top cross-sectional view shows a gate dielectric layer 202, a cathode layer 204, a sensor layer 206A, and an ITO layer 208A. The corresponding flow chart steps are depositing the gate dielectric layer 202 at step 210, depositing the cathode layer 204 at step 212, and depositing the sensor at step 214. Depositing the sensor includes depositing the sensor layer 206A and the ITO electrode layer 208A. The corresponding plan view of the ITO electrode layer 208A is also shown.

The bottom cross-sectional view shows a gate dielectric layer 202, a cathode layer 204, an etched sensor layer 206B, and an etched ITO layer 208B. The corresponding flow chart steps are using the second mask 216 (ITO) to etch the sensor layer and the ITO layer at step 218. The corresponding plan view of the etched ITO layer 208B and cathode layer 204 (as well as the active layer 106B) is also shown.

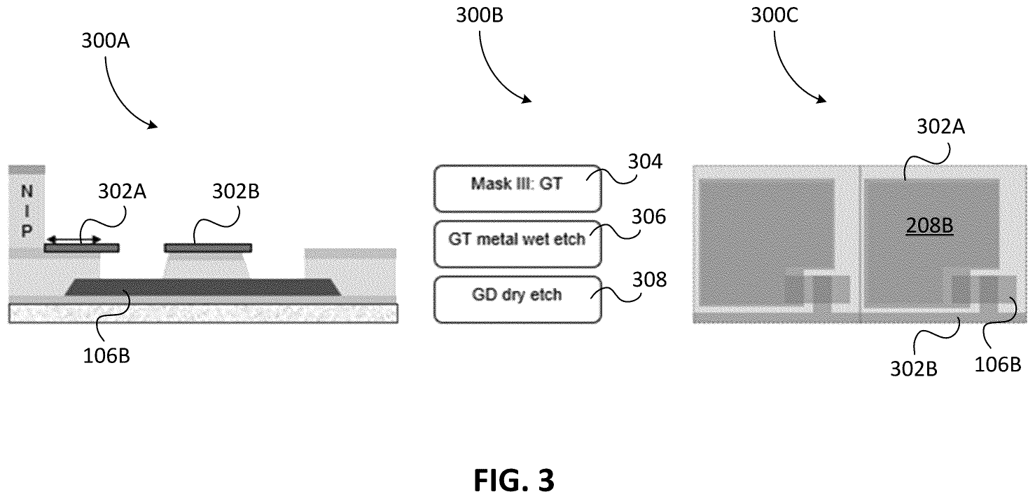

FIG. 3 shows a cross-sectional views 300A, the flow chart steps 300B, and the plan view 300C of the manufacturing steps associated with Mask 3: GT (304).

The cross-sectional view shows portions 302A and 302B of the third mask 304 on top of the ITO electrode layer 208B to define gate metal (204) and vias in the gate dielectric layer 202. The corresponding flow chart steps are using the third mask 304 to perform a top gate wet etch at step 306, and a gate dielectric dry etch at step 308. The corresponding plan view of the mask portions 302A and 302B, the etched ITO layer 208B, and the active layer 106B.

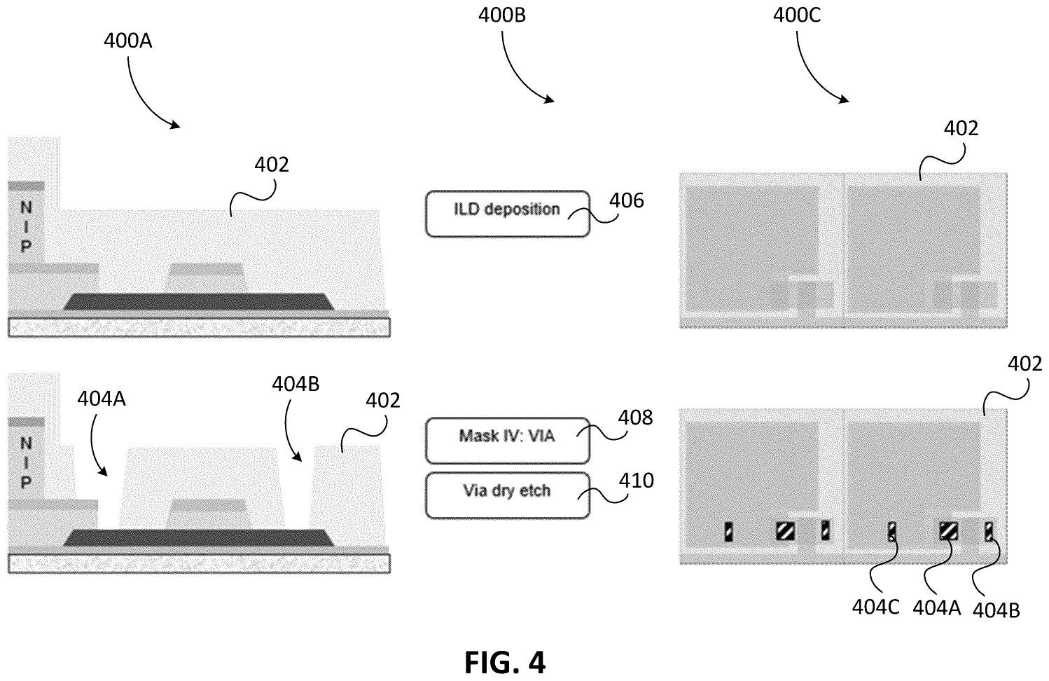

FIG. 4 shows cross-sectional views 400A, the flow chart steps 400B, and the plan view 400C of the manufacturing steps associated with Mask 4: VIA (408).

The top cross-sectional view shows an interlayer dielectric 402 deposited on the underlying layers, previously described with respect to FIGS. 1-3. The corresponding flow chart steps are depositing the interlayer dielectric deposition at step 406. The corresponding plan view of the interlayer dielectric 402 over the previously described features is also shown.

The bottom cross-sectional view shows vias 404A and 404B etched into the interlayer dielectric 402. The corresponding flow chart steps are using the fourth mask 408 to etch the vias with a dry via etch at step 410. The corresponding plan view of the interlayer dielectric 402 includes vias 404A and 404B, as well as a via 404C not previously shown in the cross-sectional view.

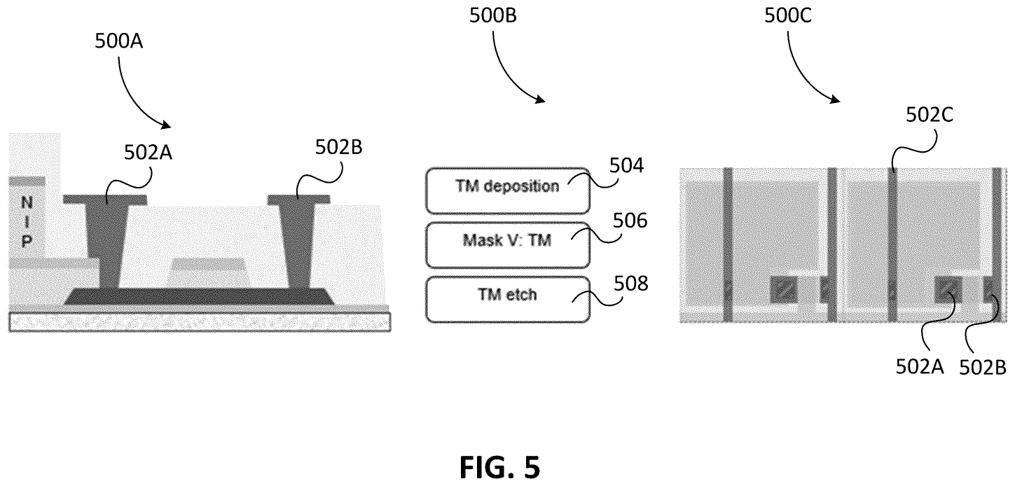

FIG. 5 shows the cross-sectional view 500A, the flow chart steps 500B, and the plan view 500C of the manufacturing steps associated with Mask 5: Top Metal.

The cross-sectional view shows the top metal layer filling both vias 404A and 404B, to form top metal portions 502A (source) and 502B (drain). The corresponding flow chart steps use the fifth mask 506 for top metal deposition at step 506, and then etching the top metal layer to form top metal portions 502A and 502B. The corresponding plan view of the etched top metal layer show top metal portions 502A, 502B, as well as top metal portion 502C not previously shown.

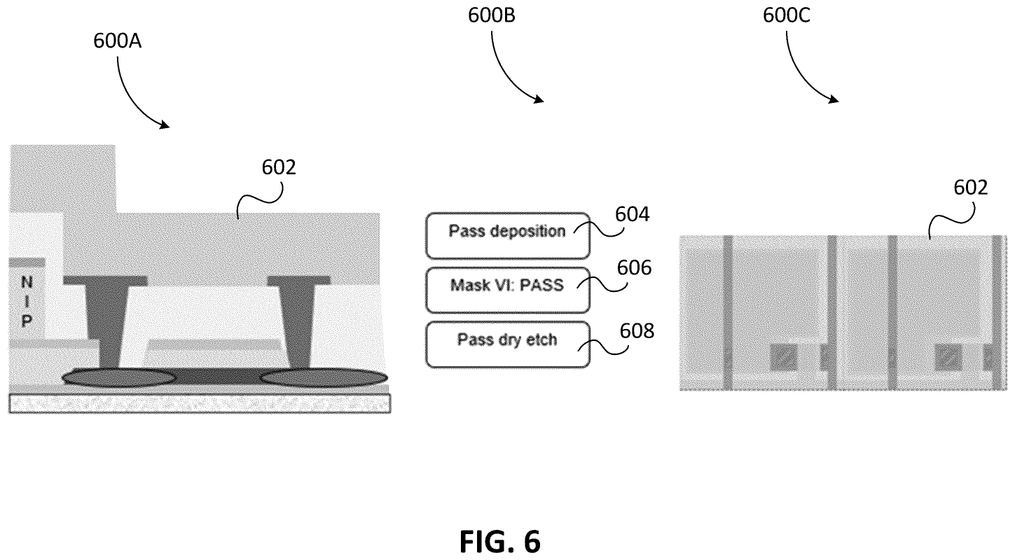

FIG. 6 shows the cross-sectional view 600A, the flow chart steps 600B, and the plan view 500C of the manufacturing steps associated with Mask 6: Passivation.

The cross-sectional view shows the passivation layer 602 cover the top metal layer portions and other features previously discussed. The corresponding flow chart steps use the sixth mask 606 for the passivation layer deposition at step 604, and a dry passivation etch at step 608. The passivation layer 602 is also shown in the corresponding plan view.

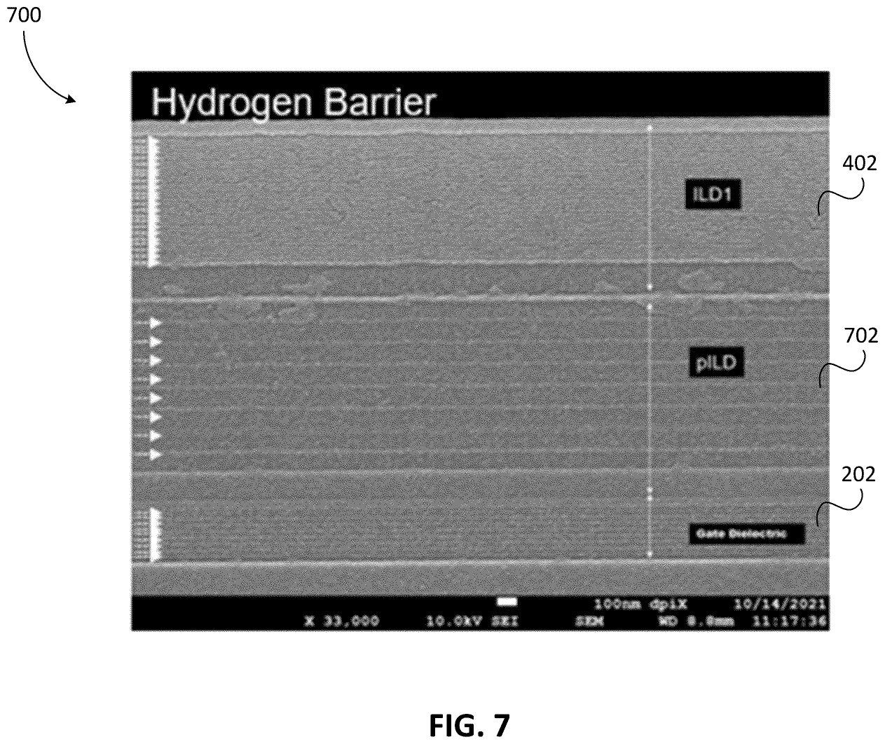

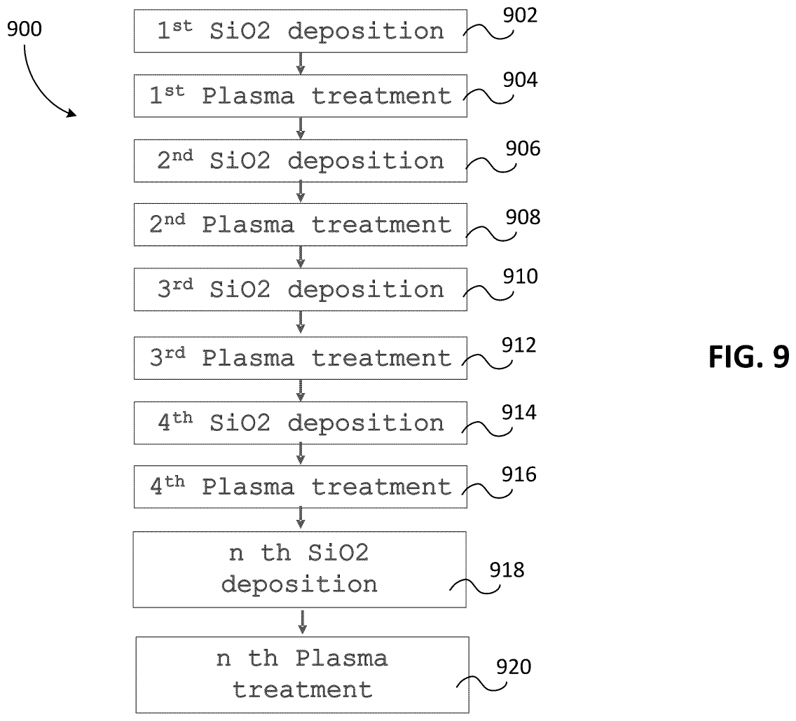

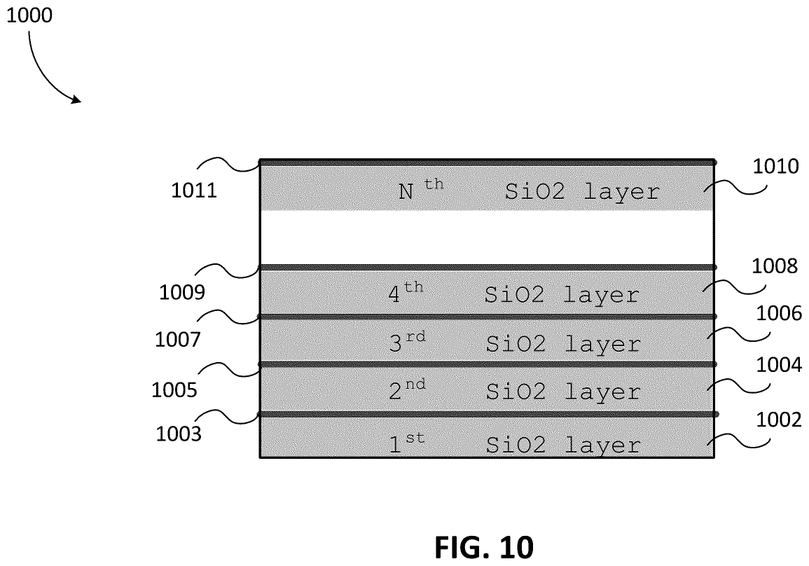

A hydrogen barrier for both the gate dielectric layer 202 and the interlayer dielectric 402 are described below, with reference to FIG. 7, FIG. 9, and FIG. 10. Two diagrams of a PECVD (Plasma-Enhanced Chemical Vapor Deposition) process for the gate dielectric layer and the interlayer dielectric are shown in FIG. 9 and FIG. 10. The PECVD process is used to substantially reduce hydrogen ([H]) mitigation. FIG. 7 shows an SEM (Scanning Electron Microscope) cross-section image showing the layered structure of a semiconductor device, highlighting the hydrogen barrier.

SEM Cross-Section Image: The SEM image of FIG. 7 shows a cross-section of a device 700 where different layers can be identified, including the gate dielectric layer 202, an ILD layer 702 and an ILD layer 402. The ‘Hydrogen Barrier’ label points to a specific layer designed to prevent hydrogen diffusion. A hydrogen barrier is advantageous in IGZO devices, as hydrogen can passivate the metal-oxide bonds in the IGZO layer, altering its electrical properties. Each of layers 402, 702, and 202 are shown as having an alternating layer structure. The alternating layers comprise SiO₂ and SiN, which is described in further detail below

The labels ‘ILD1’ and ‘pILD’ might refer to different interlayer dielectric materials used in the device, which provide insulation between different conducting layers.

The actual gate dielectric layer 202 is indicated at the bottom, which is an important part of the transistor that insulates the gate electrode from the semiconductor channel.

For IGZO transistors, the quality and composition of the gate dielectric are critical. A high-quality gate dielectric enhances the device stability and performance. In the context of the SEM image and the PECVD process, the hydrogen mitigation steps in the gate dielectric deposition process are aimed at enhancing the performance of IGZO transistors, by providing a stable and reliable dielectric layer that minimizes the detrimental effects of hydrogen incorporation into the IGZO layer. This results in improved device longevity, reliability, and electrical performance, which are especially important for high-precision applications like medical imaging.

PECVD Process Diagram: FIGS. 9 and 10 depict a PECVD process where SiH4 (silane) and process (nitrous oxide) gases are used. The SiH4 flow is controlled by a Mass Flow Controller (MFC), which is turned off and then on as part of the process steps. The process is aimed at growing a dense SiO₂ (silicon dioxide) layer while minimizing the hydrogen content, which can be detrimental to the dielectric properties.

Plasma treatments using N2O are applied to reduce hydrogen content. This is important because hydrogen can cause instability in transistor thresholds and mobility, especially in IGZO transistors where the active layer is very sensitive to hydrogen incorporation.

FIG. 9 is a flow chart 900 associated with the hydrogen barrier shown in FIG. 7. To create the hydrogen barrier a PECVD process uses a first SiO₂ deposition at step 902, a first plasma treatment at step 904, a second SiO₂ deposition at step 906, a second plasma treatment at step 908, a third SiO₂ deposition at step 910, a third plasma treatment at step 912, a fourth SiO₂ deposition at step 914, and a fourth plasma treatment at step 916. The process may be repeated for additional cycles and is completed with a last (N^{th}) SiO₂ deposition at step 918, and a last (N^{th}) plasma treatment at step 920.

FIG. 10 is a more detailed cross-sectional view of the hydrogen barrier shown in FIG. 7, according to an embodiment. A hydrogen barrier 1000 comprises a first SiO₂ layer 1002, a first SiN layer 1003, a second SiO₂ layer 1004, a second SiN layer 1005, a third SiO₂ layer 1006, a third SiN layer 1007, a fourth SiO₂ layer 1008, and a fourth SiN layer 1009. The layers continue until the last (N^{th}) SiO₂ layer 1010 is deposited, and the last (N^{th}) SiN layer 1011 is deposited. The resulting hydrogen barrier 1000 is an alternating multi-layer structure that can be used for the gate dielectric layer and any interlayer dielectrics.

In summary, embodiments described above provides a detailed architecture and method for constructing an Indium Gallium Zinc Oxide (IGZO) active matrix, optimized for integration with amorphous silicon (aSi) and Low-Temperature Polycrystalline Silicon (LTPS) processes, and designed for use in high-resolution medical imaging systems and display technologies. The above description delineates the various layers, materials, and processes involved in fabricating this advanced IGZO active matrix. The various process steps are summarized below.

### Foundation and Semiconductor Layer

The process begins with the preparation of a glass substrate upon which a thin SiO₂ buffer layer is deposited. The purpose of this buffer layer is to act as a barrier against the leaching of alkaline or other deleterious materials from the glass into the IGZO channel, which could negatively impact the semiconductor's electrical properties.

Over the buffer, a layer of PVD (Physical Vapor Deposition) IGZO is applied and patterned. The patterning process is crucial as it differentiates between the source and drain regions, which are made conductive, and the channel region beneath the gate, which remains semiconductive.

### Gate Dielectric Formation

A layer of SiO₂ is deposited using Chemical Vapor Deposition (CVD), forming the gate dielectric. This layer is subjected to intensive N2O plasma treatments to create a dense, high-quality dielectric that serves as an effective hydrogen barrier. The N2O plasma treatments are performed at high power levels (3-10 kW per square meter) to ensure the dielectric has the requisite density to prevent hydrogen diffusion, which is particularly problematic in IGZO devices.

### Hydrogen Barrier Enhancement through Plasma Treatments

According to embodiments, the formation of an advantageously robust hydrogen barrier within the gate dielectric and interlayer dielectric, is achieved through specialized plasma treatments. This aspect of these embodiments is advantageous in addressing the problem of hydrogen-induced conductivity, which has been a significant challenge in the integration of IGZO with existing semiconductor processes.

Gate Dielectric Hydrogen Barrier: After the deposition of the SiO₂ gate dielectric layer, the substrate undergoes a sequence of specific plasma treatments. These treatments are engineered to significantly reduce the hydrogen content within the dielectric.

The plasma power for these treatments is maintained at high levels, ranging from 3 to 10 kW per square meter. This high-energy plasma environment allows for the formation of a dense SiN-like barrier at intervals of every 10 Angstroms within the SiO₂ matrix, creating a composite structure.

The total thickness of the gate dielectric, incorporating these dense SiN barriers, is targeted to be approximately 3000 Angstroms. This composite structure is designed to obstruct the diffusion of hydrogen atoms effectively, thereby maintaining the semiconducting integrity of the underlying IGZO layer.

Interlayer Dielectric Hydrogen Barrier: Similarly, the interlayer dielectric encapsulating the sensor and interconnect layers is subjected to plasma treatments. The process parameters mirror those of the gate dielectric hydrogen barrier, ensuring consistency in barrier properties throughout the device.

The high-density SiN barriers integrated within the interlayer dielectric serves a dual purpose. They not only protect the sensor layer from hydrogen infiltration but also provide a secondary hydrogen diffusion barrier to the underlying IGZO TFT, further enhancing device stability and longevity.

The implementation of these hydrogen barriers through plasma treatments is an advantageous approach that provides a significant improvement over conventional dielectric layers. By integrating the barrier within the dielectric itself, rather than as a separate layer, the efficacy of hydrogen blocking is substantially improved while minimizing the impact on the overall device structure and performance.

### Cathode and Sensor Layers

The cathode structure is composed of a PVD metal electrode stack, typically TiW/Aluminum/TiW. The TiW layers serve as a refractory material that withstands subsequent high-temperature processes without diffusing into the IGZO and altering its properties. This layer acts as the bottom electrode of the photodiode and also forms the contact with the drain of the IGZO TFT.

A sensor layer is then deposited, which may consist of an aSi-based photodiode structure with an NIP configuration, capped with an ITO electrode. The sensor layer is patterned to create the photodiode and the metal electrodes for the gate and cathode/drain connections.

### Interlayer Dielectric and Via Formation

An interlayer dielectric is applied over the sensor layer. This encapsulation typically involves layers of SiON or SiO₂, capped with SiN to further enhance the hydrogen barrier properties. The dielectric is patterned to form vias, which provide the electrical connections to the cathode of the a-Si photodiode and the source of the IGZO TFT.

### Top Metal and Signal Readout

A top metal layer, again utilizing a TiW/Aluminum/TiW stack, is deposited. This layer is patterned to form the necessary interconnections, including those to the cathode of the diode and the drain of the TFT. The thickness of the top metal layer (>1 μm) is specifically chosen to ensure rapid signal switching, which is vital for reducing TFT noise and improving the readout speed.

### Passivation and Completion

An optional passivation layer can be applied to protect the interlayer and top metal from environmental factors and mechanical abrasion. Openings are then etched into the passivation layer to expose areas for external electrical connections.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A semiconductor device comprising an active matrix, using Indium Gallium Zinc Oxide (IGZO) as a semiconductor layer, wherein the IGZO is patterned to create distinct conductive and semiconductive regions across the active matrix, and wherein the semiconductor device comprises an IGZO TFT.

2. The semiconductor device of claim 1, wherein a SiO₂ buffer layer is deposited on a glass substrate to mitigate diffusion of contaminants into the IGZO layer.

3. The semiconductor device of claim 1, wherein a gate dielectric layer comprises multi-SiO₂ layers subjected to plasma treatments to form a high-density SiN barrier to hydrogen penetration.

4. The semiconductor device of claim 3, wherein the plasma treatments are performed with plasma powers ranging from 0.5 to 10 kW per square meter, creating SiN barriers at intervals of every 5˜30 Angstroms within the multi-SiO₂ layers to a total thickness of approximately 3000 Angstroms.

5. The semiconductor device of claim 1, further comprising a cathode structure made of a TiW/Aluminum/TiW stack, where the TiW/Aluminum/TiW stack comprises a refractory material to prevent doping of the IGZO layer.

6. The semiconductor device of claim 5, wherein the cathode structure serves as a bottom anode for a photodiode and forms a contact with a drain of the IGZO TFT.

7. The semiconductor device of claim 1, further comprising a sensor layer formed from a CVD-deposited aSi photodiode structure, capped with an ITO electrode, and patterned to create photodiode and metal electrode structures.

8. The semiconductor device of claim 7, further comprising an interlayer dielectric encapsulation consisting of SiON or SiO, capped with SiN, patterned with vias to provide electrical connections to a cathode of the CVD-deposited aSi photodiode structure and a source of the IGZO TFT.

9. The semiconductor device of claim 1, further comprising a top metal layer formed from a TiW/Aluminum/TiW stack, patterned to facilitate rapid signal switching and minimize TFT noise.

10. The semiconductor device of claim 9, wherein the top metal layer has a thickness greater than 1 micron to ensure fast rise and fall times for signal readout.

11. A method for manufacturing a semiconductor device, wherein the semiconductor device comprises an IGZO TFT, the method comprising depositing and patterning an IGZO layer on a SiO₂ buffer layer to create an active matrix with differentiated conductive and semiconductive regions.

12. The method of claim 11, further comprising the steps of applying N2O plasma treatments to a SiO₂ gate dielectric layer to integrate SiN barriers at defined intervals and thicknesses for hydrogen diffusion prevention.

13. The method of claim 11, wherein a multi-layer cathode structure is deposited using PVD, forming a bottom electrode of a photodiode and providing electrical contact a drain of the IGZO TFT.

14. The method of claim 11, wherein a sensor layer deposition and patterning of a sensor layer comprise CVD techniques to form an aSi photodiode structure with an NIP configuration and an ITO electrode cap.

15. The method of claim 14, further comprising encapsulating the sensor layer with an interlayer dielectric, patterned with vias for electrical connectivity within the semiconductor device.

16. The method of claim 14, wherein a top metal layer deposition and patterning are conducted to connect to a cathode of the aSi photodiode structure and a drain of the IGZO TFT with reduced noise characteristics.

17. The semiconductor device of claim 1, wherein an optional passivation layer is applied, with openings etched for external electrical connections.

18. The semiconductor device of claim 1, wherein the active matrix is adaptable for integration with amorphous silicon (a-Si) and Low-Temperature Polycrystalline Silicon (LTPS) process technologies.

19. A method of manufacturing an image sensor, the method comprising:
forming a patterned Indium Gallium Zinc Oxide (IGZO) layer on a buffer layer over a substrate;
forming a gate dielectric layer over the patterned IGZO layer;
forming a sensor over a portion of the gate dielectric layer;
encapsulating the sensor with an interlayer dielectric layer;
forming vias in the interlayer dielectric layer; and
metalizing the vias in the interlayer dielectric layer,
wherein the gate dielectric layer and the interlayer dielectric layer are both subjected to plasma treatments to form a dual hydrogen barrier.

20. The method of claim 19, wherein the gate dielectric layer comprises a first silicon dioxide layer, wherein the interlayer dielectric layer comprises a second silicon dioxide layer, and wherein the plasma treatments form a plurality of silicon nitride barriers within the gate dielectric layer and within the interlayer dielectric layer.
